(19) United States
(12) Patent Application Publication
(10) Pub. No.: US 2025/0311099 A1
(43) Pub. Date: Oct. 2, 2025

(54) METHOD FOR MANUFACTURING WIRING SUBSTRATE

(71) Applicant: IBIDEN CO., LTD., Ogaki (JP)

(72) Inventors: Toshihide MAKINO, Ibi-gun (JP); Ayumu KUBOTA, Ibi-gun (JP)

(73) Assignee: IBIDEN CO., LTD., Ogaki (JP)

(21) Appl. No.: 19/089,043

(22) Filed: Mar. 25, 2025

(30) Foreign Application Priority Data
Mar. 26, 2024 (JP) 2024-050011

(51) Int. Cl. H05K 1/03; H05K 3/46

(52) U.S. Cl. CPC H05K 1/0306; H05K 3/4644; H05K 2201/068

(57) ABSTRACT

A method for manufacturing a wiring substrate includes preparing a glass substrate having one or more product areas on a surface, and forming a build-up part on the surface across the product area. The one or more product areas have a rectangular shape with each side in range of 80 mm to 240 mm, the forming the build-up part includes alternately laminating three or more conductor layers and three or more insulating layers such that difference in thermal expansion coefficient between the substrate and insulating layers is 13 ppm/° C. or less, the laminating the conductor layers includes forming a resist layer having resist pattern and forming conductor pattern including wirings according to the pattern such that the wirings have the minimum width of 2 μm or less and the minimum inter-wiring distance of 2 μm or less, and the forming the resist includes exposing the resist by direct imaging exposure.

### CROSS-REFERENCE TO RELATED APPLICATIONS

The present application is based upon and claims the benefit of priority to Japanese Patent Application No. 2024-050011, filed Mar. 26, 2024, the entire contents of which are incorporated herein by reference.

### BACKGROUND OF THE INVENTION

### Field of the Invention

The present invention relates to a method for manufacturing a wiring substrate.

### Description of Background Art

Japanese Patent Application Laid-Open Publication No. 2020-4926 describes a method for manufacturing a wiring substrate. The entire contents of this publication are incorporated herein by reference.

### SUMMARY OF THE INVENTION

According to one aspect of the present invention, a method for manufacturing a wiring substrate includes preparing a glass substrate having one or more product areas formed on a surface thereof, and forming a build-up part including conductor layers and insulating layers on the surface of the glass substrate across the one or more product areas. The glass substrate is formed such that the one or more product areas have a rectangular shape with each side in a range of 80 mm to 240 mm, the forming the build-up part includes alternately laminating three or more conductor layers and three or more insulating layers such that a difference in thermal expansion coefficient between the glass substrate and the insulating layers is 13 ppm/° C. or less, the laminating the conductor layers includes forming a resist layer having a resist pattern and forming a conductor pattern including wirings according to the resist pattern such that the wirings have the minimum width of 2 μm or less and the minimum inter-wiring distance of 2 μm or less, and the forming the resist layer includes exposing the resist layer by direct imaging exposure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate manufactured using a manufacturing method according to an embodiment of the present invention;

FIG. 2 is a cross-sectional view illustrating another example of a wiring substrate manufactured using a manufacturing method according to an embodiment of the present invention;

FIG. 3A illustrates an example of a method for manufacturing a wiring substrate according to an embodiment of the present invention;

FIG. 3B illustrates an example of a method for manufacturing a wiring substrate according to an embodiment of the present invention;

FIG. 3C illustrates an example of a method for manufacturing a wiring substrate according to an embodiment of the present invention;

FIG. 3D illustrates an example of a method for manufacturing a wiring substrate according to an embodiment of the present invention;

FIG. 3E illustrates an example of a method for manufacturing a wiring substrate according to an embodiment of the present invention;

FIG. 3F illustrates an example of a method for manufacturing a wiring substrate according to an embodiment of the present invention;

FIG. 3G illustrates an example of a method for manufacturing a wiring substrate according to an embodiment of the present invention;

FIG. 3H illustrates an example of a method for manufacturing a wiring substrate according to an embodiment of the present invention;

FIG. 3I illustrates an example of a method for manufacturing a wiring substrate according to an embodiment of the present invention;

FIG. 3J illustrates an example of a method for manufacturing a wiring substrate according to an embodiment of the present invention;

FIG. 3K illustrates an example of a method for manufacturing a wiring substrate according to an embodiment of the present invention;

FIG. 3L illustrates an example of a method for manufacturing a wiring substrate according to an embodiment of the present invention;

FIG. 3M illustrates an example of a method for manufacturing a wiring substrate according to an embodiment of the present invention;

FIG. 3N illustrates an example of a method for manufacturing a wiring substrate according to an embodiment of the present invention;

FIG. 3O illustrates an example of a method for manufacturing a wiring substrate according to an embodiment of the present invention; and

FIG. 3P illustrates an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

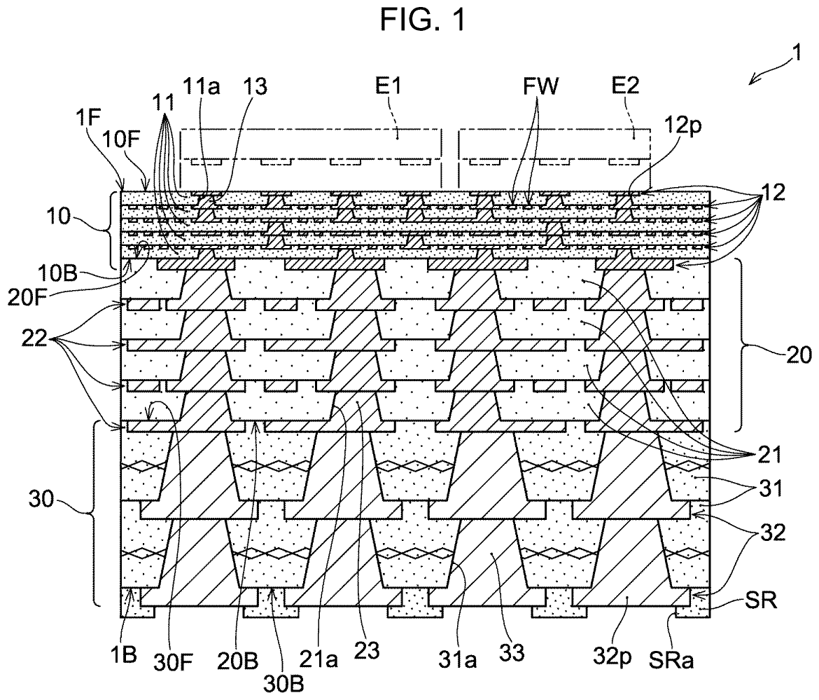

FIG. 1 is a cross-sectional view illustrating a wiring substrate 1, which is an example of a wiring substrate manufactured using a manufacturing method according to an embodiment of the present invention. A laminated structure, as well as the number of conductor layers and insulating layers, of the wiring substrate to be manufactured are not limited to the laminated structure of the wiring substrate 1 in FIG. 1, and the number of conductor layers and insulating layers included in the wiring substrate 1.

The wiring substrate 1 has a laminated structure that includes a build-up part, which is formed of alternately laminated multiple conductor layers and insulating layers. The build-up part constituting the wiring substrate 1 has two surfaces (a first surface (1F) and a second surface (1B) on the opposite side with respect to the first surface (1F)) orthogonal to a thickness direction thereof. The build-up part of a wiring substrate manufactured using the method for manufacturing a wiring substrate of the embodiment includes at least a build-up part 10, as illustrated in FIG. 1. A surface (first surface (10F)) of the build-up part 10 constitutes the first surface (1F).

The build-up part 10 has a second surface (10B) as a surface on the opposite side with respect to the first surface (10F). As illustrated in FIG. 1, the wiring substrate 1 can further include build-up parts (20, 30), which are each constituted by alternately laminated insulating layers and conductor layers, on the second surface (10B) side of the build-up part 10. In the following description of the wiring substrate 1, the build-up part 10 is also referred to as the first build-up part 10, the build-up part 20 is also referred to as the second build-up part 20, and the build-up part 30 is also referred to as the third build-up part 30.

The second build-up part 20 has a first surface (20F) and a second surface (20B), which is a surface on the opposite side with respect to the first surface (20F). The third build-up part 30 has a first surface (30F) and a second surface (30B), which is a surface on the opposite side with respect to the first surface (30F). As illustrated, when the wiring substrate has, in addition to the first build-up part 10, the second build-up part 20 and the third build-up part 30, the first surface (20F) of the second build-up part 20 is formed to face the second surface (10B) of the first build-up part 10, and the first surface (30F) of the third build-up part 30 is formed to face the second surface (20B) of the second build-up part 20.

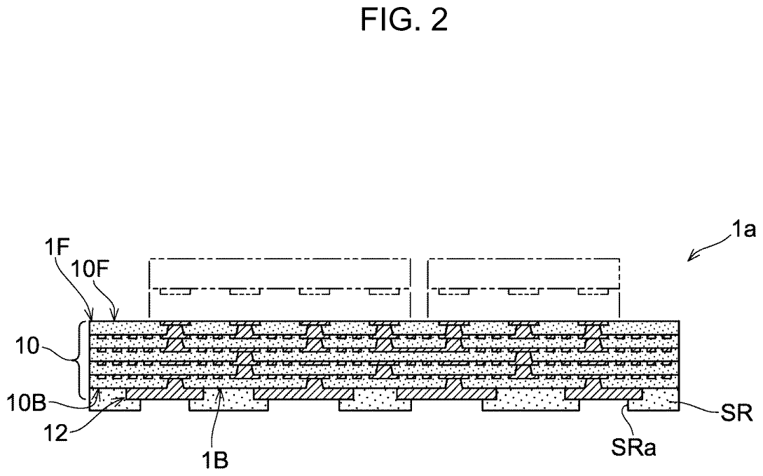

When the wiring substrate 1 has, in addition to the first build-up part 10, the second build-up part 20 and the third build-up part 30, the second surface (1B) of the wiring substrate 1 can be constituted by the surface (second surface (30B)) of the third build-up part 30. When the third build-up part 30 is not formed, and the build-up part of the wiring substrate is constituted by the first build-up part 10 and the second build-up part 20, the second surface (1B) can be constituted by the surface (second surface (20B)) of the second build-up part 20. Further, as will be described later with reference to FIG. 2, when the second build-up part 20 and the third build-up part 30 are not formed, and the build-up part of the wiring substrate is constituted by the first build-up part 10, the second surface (1B) can be constituted by the surface (second surface (10B)) of the first build-up part 10. The wiring substrate 1 is formed as a coreless wiring substrate that does not include a core layer.

The first build-up part 10 includes relatively fine wirings, and can have relatively dense circuit wirings. The first build-up part 10 includes alternately laminated insulating layers (first insulating layers) 11 and conductor layers (first conductor layers) 12. In a wiring substrate manufactured using the method for manufacturing a wiring substrate of the embodiment, the first build-up part 10 includes at least three first insulating layers 11 and at least three first conductor layers 12. In the illustrated example, the first build-up part 10 includes five first insulating layers 11 and six first conductor layers 12.

Conductor layers 12 facing each other with one first insulating layer 11 in between are connected by via conductors (first via conductors) 13. The first conductor layers 12 are each patterned to have predetermined conductor patterns. The first surface (10F) of the first build-up part 10 is constituted by a surface (upper surface) of a first conductor layer 12 and a surface (upper surface) of a first insulating layer 11 exposed from the patterns of the conductor layer 12. The second surface (10B) of the first build-up part 10 is constituted by a surface (lower surface) of an insulating layer 11 and a surface (including lower and side surfaces) of a conductor layer 12. In the illustrated example, the conductor layer 12 constituting the first surface (10F) is formed to have patterns including multiple conductor pads (12p).

In the description of the wiring substrate 1 illustrated in FIG. 1, the first surface (10F) side of the first build-up part 10, that is, the first surface (1F) side of the build-up part constituting the wiring substrate 1 is referred to as “upper” or an “upper side,” and the second surface (1B) side of the wiring substrate 1 is referred to as “lower” or a “lower side.” Further, for each of the structural elements, a surface facing the first surface (1F) side is also referred to as an “upper surface,” and a surface facing the second surface (1B) side is also referred to as a “lower surface.”

In the illustrated example, the conductor pads (12p) constitute a component mounting surface of the wiring substrate 1, which is an uppermost surface of the first build-up part 10, that is, an outermost surface of the wiring substrate 1, and on which an external electronic component can be mounted. The component mounting surface of the wiring substrate 1 may have multiple component mounting regions. For example, as illustrated in the example of FIG. 1, two component mounting regions may be formed corresponding to regions where electronic components (E1, E2) are to be mounted. In mounting external electronic components to the wiring substrate 1 in the illustrated example, upper surfaces of the conductor pads (12p) can be electrically and mechanically connected to the external electronic components, for example, via a conductive bonding material such as solder (not illustrated in the drawings) interposed between the conductor pads (12p) and connection pads of the external electronic components. In this case, for example, a plating layer (not illustrated in the drawings) including a nickel layer and a tin layer may be formed in advance on the upper surfaces of the conductor pads (12p). Examples of the electronic components (E1, E2) that can be mounted on the wiring substrate 1 include electronic components such as active components such as semiconductor integrated circuit devices and transistors.

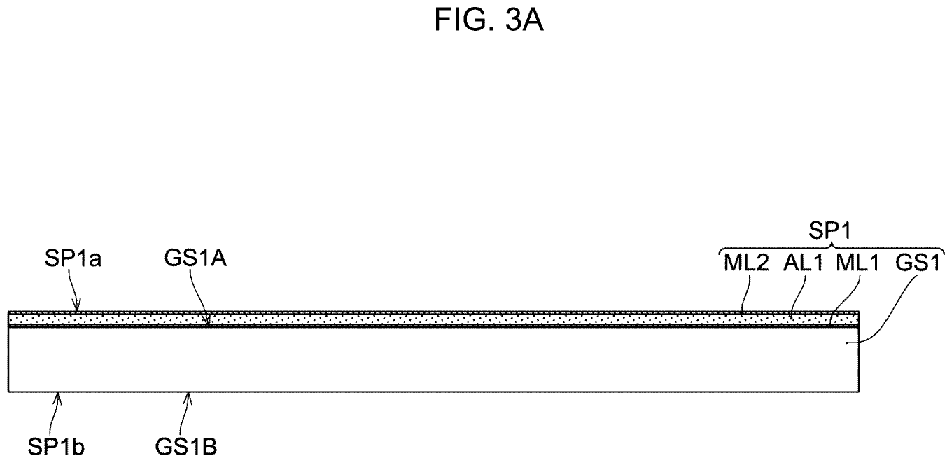

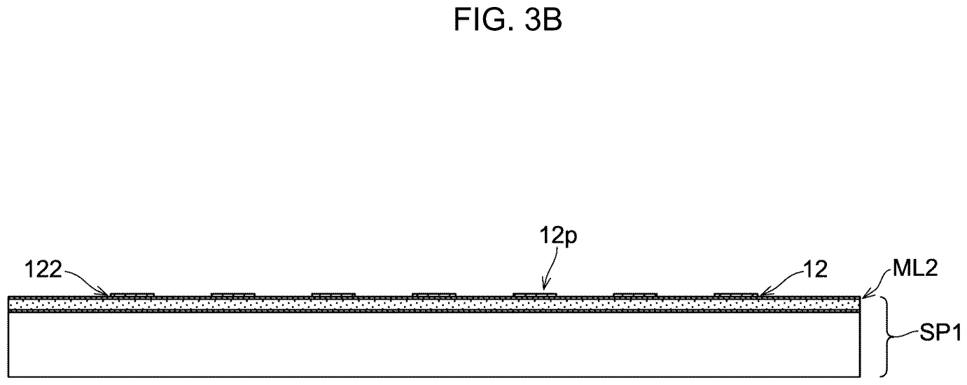

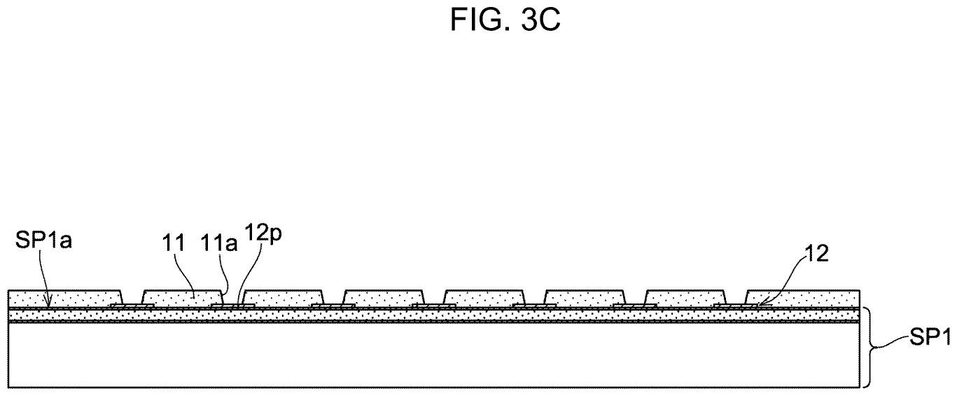

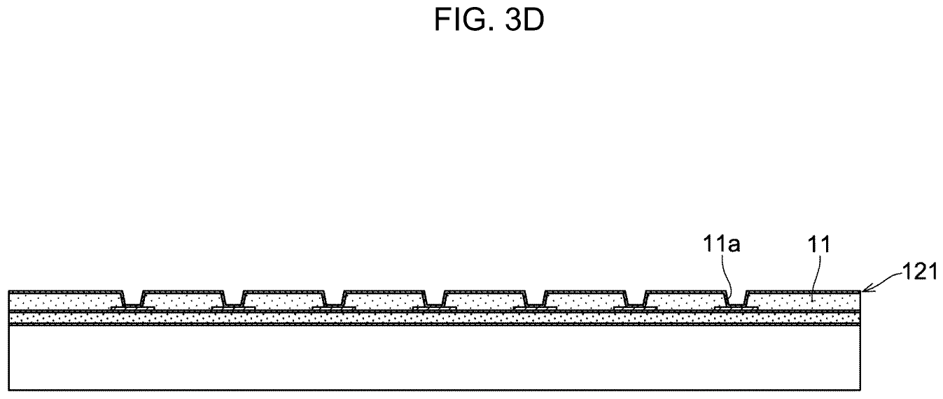

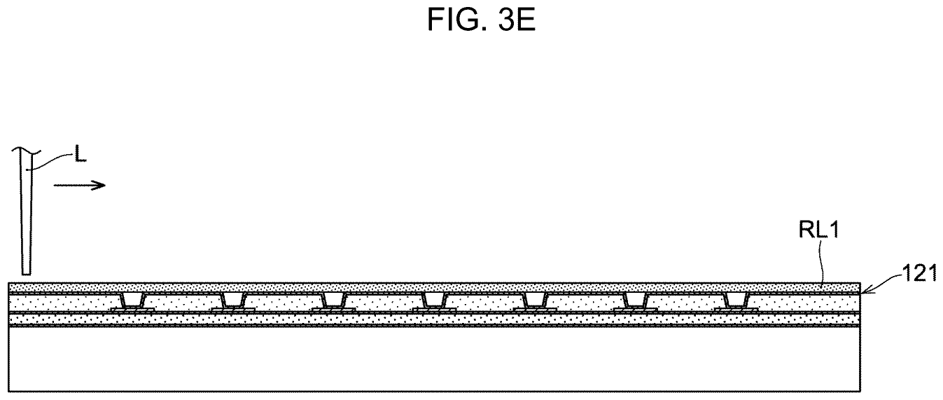

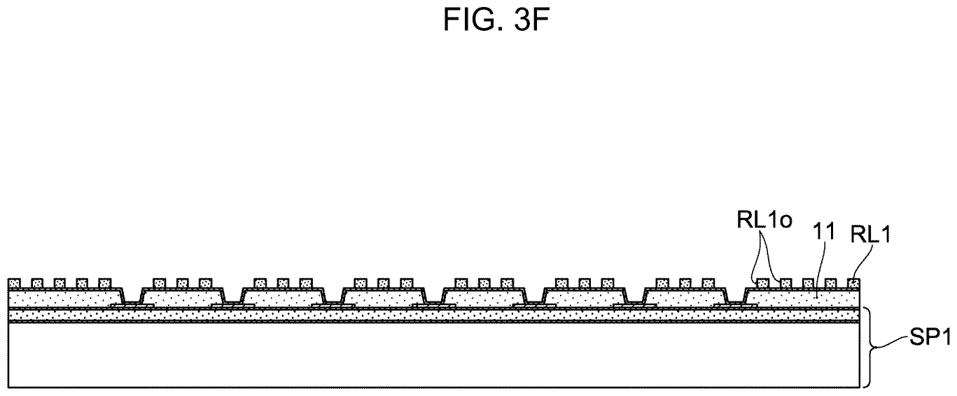

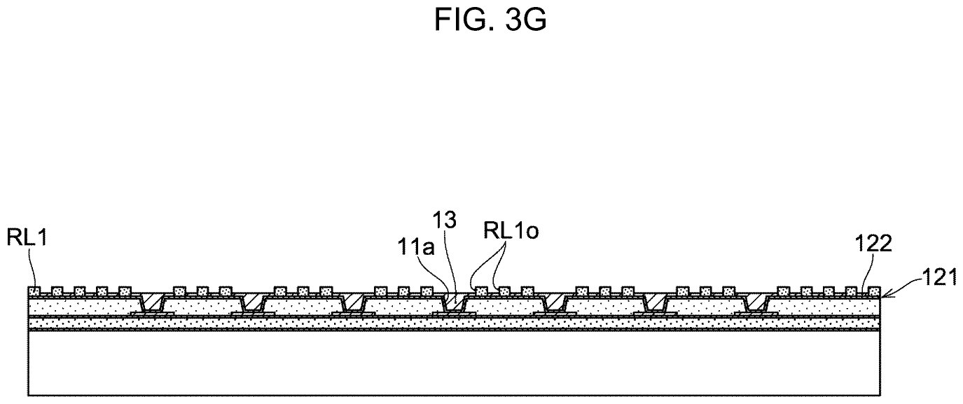

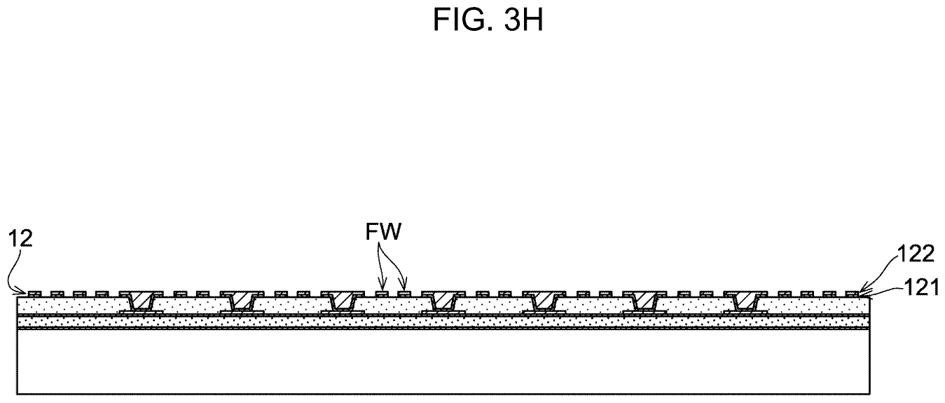

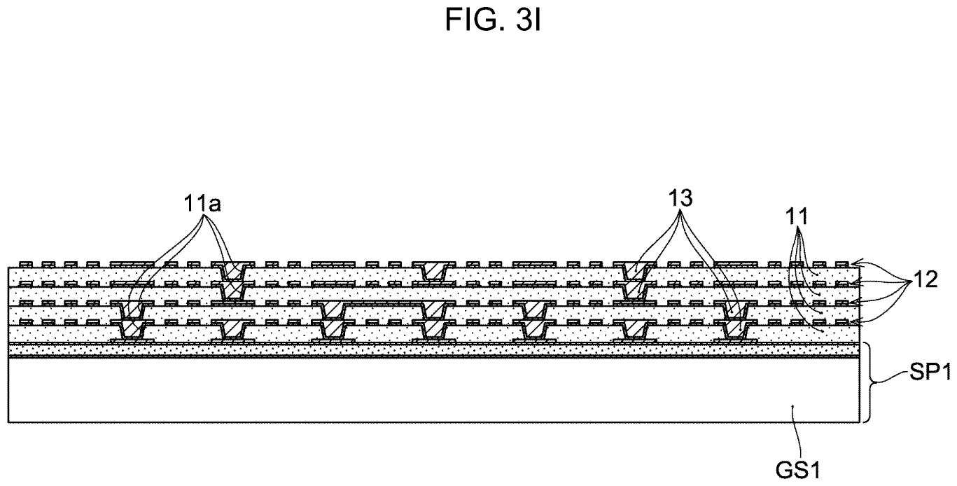

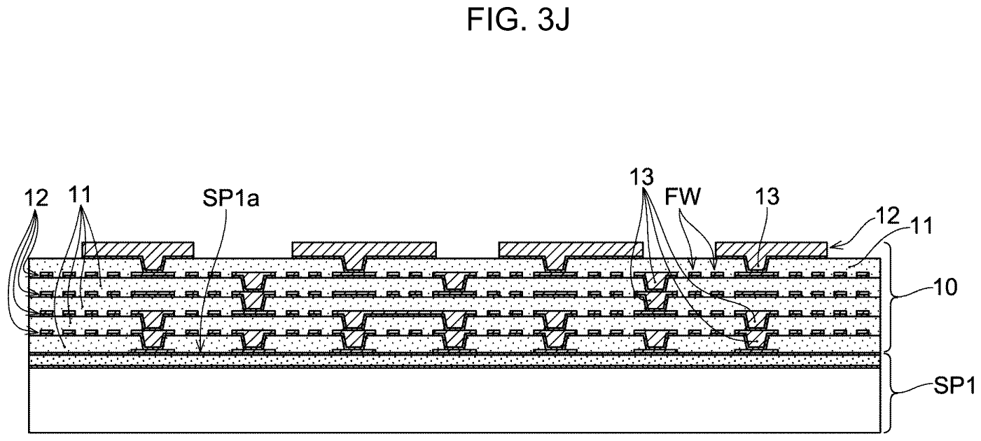

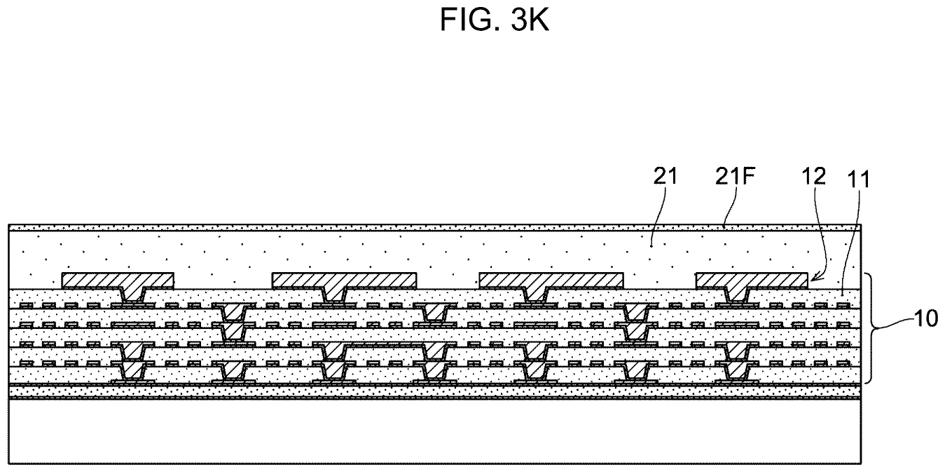

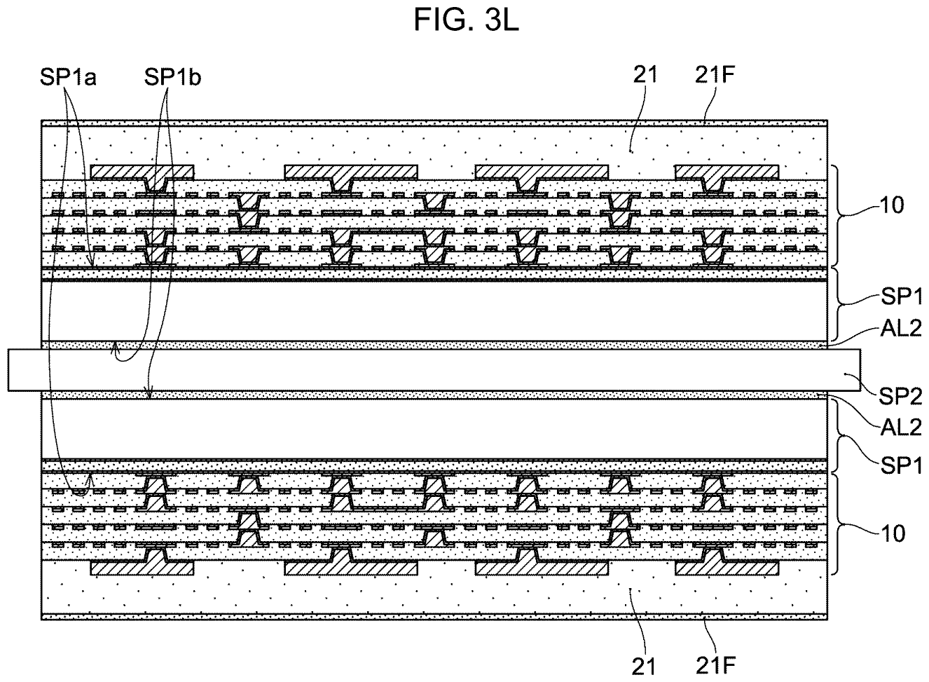

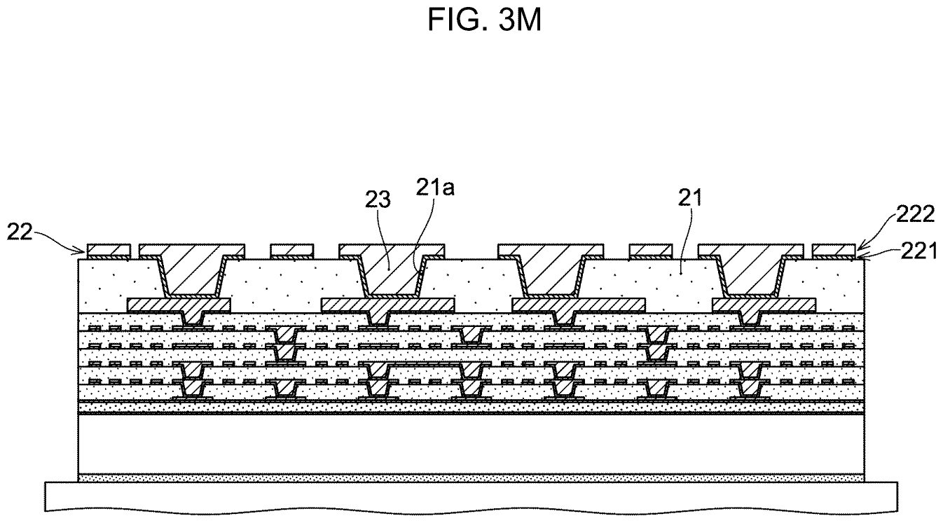

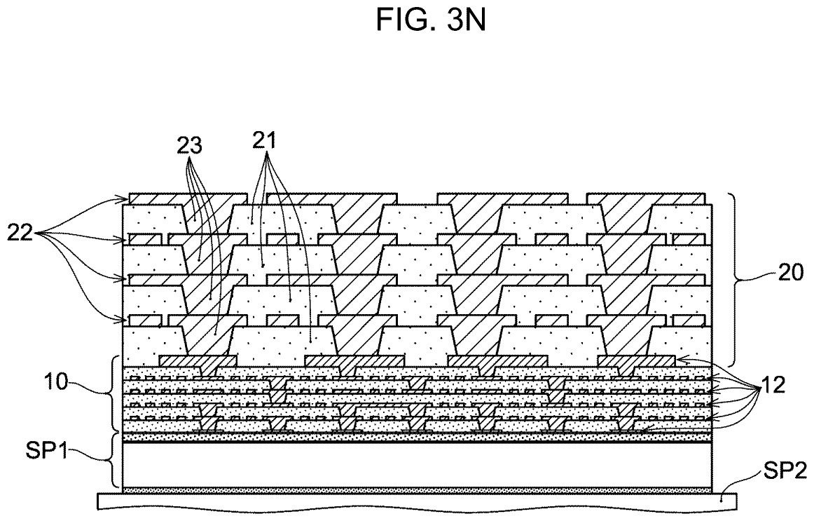

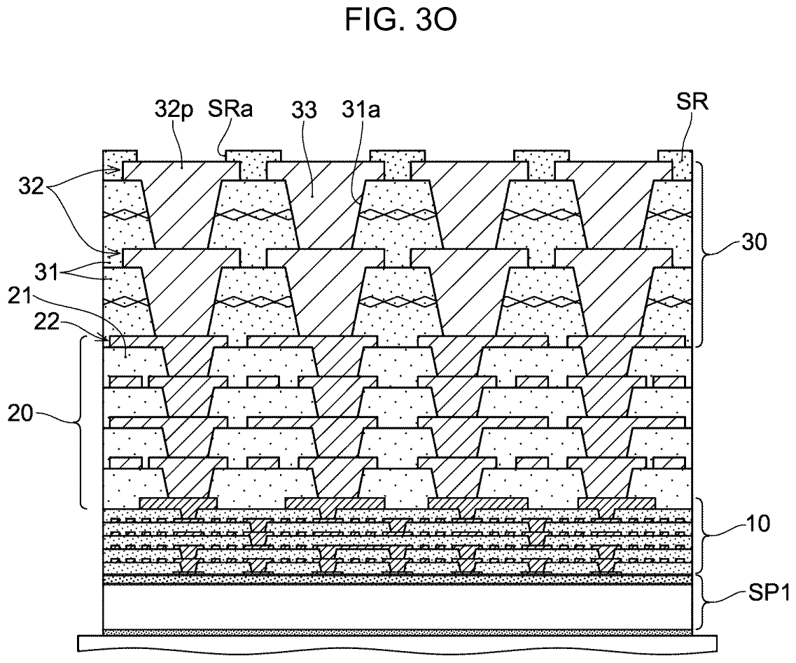

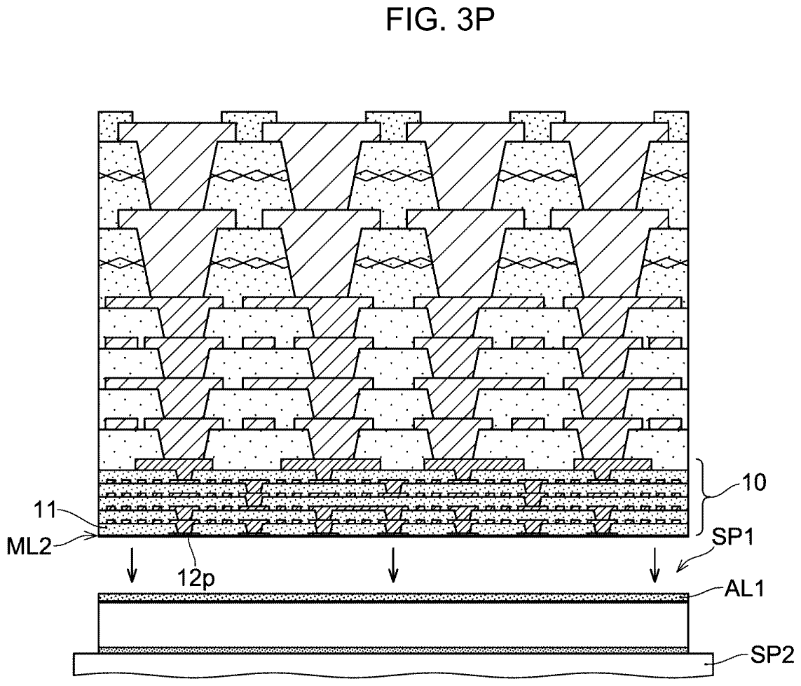

The first insulating layers 11 of the first build-up part 10 can be formed, for example, using an insulating resin such as an epoxy resin or a phenol resin. The first insulating layers 11 may contain one of a fluorine resin, a liquid crystal polymer (LCP), a fluoroethylene resin (PTFE), a polyester resin (PE), and a modified polyimide resin (MPI). As will be described later with reference to FIGS. 3A to 3P, a material constituting the first insulating layers 11 is selected such that a difference in thermal expansion coefficient between the material and a glass substrate on a surface of which the first build-up part 10 is formed falls within a predetermined range. As the material constituting the first insulating layers 11, for example, a resin material with a thermal expansion coefficient of 25 ppm/° C. or less is preferably selected.

Examples of a conductor constituting the conductor layers 12 and the via conductors 13 include copper, nickel, and the like, and copper is preferably used. In FIG. 1, for ease of viewing, the conductor layers 12 and the via conductors 13 are each illustrated as having a single-layer structure. However, the conductor layers 12 and the via conductors 13 can each have a multilayer structure. For example, the conductor layers 12 and the via conductors 13 can each have a two-layer structure including a metal film layer (for example, a sputtering film layer or an electroless plating film layer) and a plating film layer (for example, an electrolytic plating film layer).

Each via conductor 13 penetrating an insulating layer 11 in the thickness direction is formed by filling a through hole (11a) penetrating the insulating layer 11 with a conductor. In the example of FIG. 1, each via conductor 13 is integrally formed with a conductor layer 12 provided on a lower side thereof. Therefore, the via conductor 13 and the conductor layer 12 can be formed by the same metal film layer and plating film layer. For example, the through holes (11a) are formed such that an aspect ratio of each via conductor 13 ((height from the upper surface of the lower conductor layer 12 to the lower surface of the upper conductor layer, the lower and upper conductor layers being connected by the via conductor 13)/(diameter of the via conductor 13 at the upper surface of the lower conductor layer 12)) is about 0.5 or more and about 1.0 or less. A via diameter of each via conductor 13 (a diameter of the via conductor 13 at the upper surface of the lower conductor layer 12 to which the via conductor 13 is connected) is about 10 μm. Although the term “diameter” is used, a planar shape of each of the via conductors 13 is not necessarily limited to a circular shape. The term “diameter” means a longest distance between two points on an outer circumference in a horizontal cross section of each of the via conductors 13.

The conductor layers 12 constituting the first build-up part 10 can have fine wirings (FW), which are high-density wirings with relatively small wiring widths and inter-wiring distances (wiring spacings). The fine wirings (FW) can have smallest wiring width and inter-wiring distance among wirings that constitute the wiring substrate 1. The fine wirings (FW) included in the first build-up part 10 can have smaller wiring widths than wirings that can be included in conductor layers 22 of the second build-up part 20 and wirings that can be included in conductor layers 32 of the third build-up part 30, which will be described later. The fine wirings (FW) included in the first build-up part 10 can have smaller inter-wiring distances (wiring spacings) than the wirings that can be included in the conductor layers 22 of the second build-up part 20 and the wirings that can be included in the conductor layers 32 of the third build-up part 30, which will be described later.

Specifically, for example, the fine wirings (FW) have a minimum wiring width of 2 μm or less, and a minimum inter-wiring distance of 2 μm or less. Since the first build-up part 10 has the fine wirings (FW), it may be possible to provide wirings with more appropriate characteristics corresponding to electrical signals that can be transmitted via the wirings in the first build-up part 10. From a similar point of view, the fine wirings (FW) that can be included in the first conductor layers 12 each have an aspect ratio of, for example, 2.0 or more and 4.0 or less. As will be described later in detail with reference to FIGS. 3A to 3P, a wiring substrate 1 including such relatively fine wirings (FW) is formed with greater precision.

When the conductor layers 12 are formed to include the fine wirings (FW) as described above, it may be preferable that the via conductors 13 connecting opposing conductor layers 12 via an insulating layer 11 are also formed at a fine pitch. The through holes (11a) for the via conductors 13 with small diameters can be formed in the insulating layers 11. Therefore, although the insulating layers 11 can contain inorganic fillers such as fine particles of silica (SiO₂), alumina, mullite, or the like, in order to facilitate the formation of the through holes (11a) with small diameters, it may be preferred that the insulating layers 11 do not contain inorganic fillers.

In the first build-up part 10 including the conductor layers 12 including the fine wirings (FW), the insulating layers 11 each have a thickness of, for example, about 7.5 μm to 10 μm. The insulating layers 11 preferably do not each contain a core material (reinforcing material) formed of glass fiber, aramid fiber, or the like. The conductor layers 12 each have a thickness of, for example, 7 μm or less.

The second build-up part 20 includes alternately laminated insulating layers (second insulating layers) 21 and conductor layers (second conductor layers) 22. In the second insulating layers 21, via conductors 23 are formed, each penetrating a second insulating layer 21 and connecting conductor layers that oppose each other across the second insulating layer 21. The conductor layers 22 are each patterned to have predetermined conductor patterns. The third build-up part 30 includes alternately laminated insulating layers (third insulating layers) 31 and conductor layers (third conductor layers) 32. In the third insulating layers 31, via conductors 33 are formed, each penetrating a third insulating layer 31 and connecting conductor layers that oppose each other across the third insulating layer 31. The conductor layers 32 are each patterned to have predetermined conductor patterns.

The insulating layers 21 constituting the second build-up part 20 and the insulating layers 31 constituting the third build-up part 30 can be formed using an insulating resin similar to that used for the insulating layers 11. The insulating layers (21, 31) may each contain a core material (reinforcing material) formed of glass fiber or aramid fiber. In the illustrated example, the insulating layers 31 of the third build-up part 30 each contain a core material formed of glass fiber. The insulating layers (21, 31) can each further contain an inorganic filler (not illustrated) formed of fine particles of silica (SiO₂), alumina, mullite, or the like. Similar to the conductor layers 12 and the via conductors 13, the conductor layers 22 of the second build-up part 20 and the conductor layers 32 of the third build-up part 30, as well as the via conductors (23, 33), can be formed using any metal such as copper or nickel.

As described above, the wiring widths and inter-wiring distances of the wirings that can be included in the conductor layers 22 of the second build-up part 20 and the conductor layers 32 of the third build-up part 30 can be larger than the wiring widths and inter-wiring distances of the wirings included in the conductor layers 12 of the first build-up part 10. For example, the wirings included in the conductor layers 22 have a minimum wiring width of about 4 μm and a minimum inter-wiring distance of about 6 μm. Further, the insulating layers (21, 31) are each formed thicker than each of the insulating layers 11, and the insulating layers 21 can each have a thickness of, for example, about 20 μm to 30 μm. The insulating layers 31 can each have a thickness of, for example, 100 μm or more and 200 μm or less.

Further, the conductor layers (22, 32) are each formed thicker than each of the conductor layers 12, and can each have a thickness of, for example, 10 μm or more. The conductor layers 32 can each have a thickness of, for example, about 20 μm. A via diameter of a via conductor 23 formed in an insulating layer 21 (a diameter of the via conductor 23 at the upper surface of the lower conductor layer 22 to which the via conductor 23 is connected) is about 50 μm. A via diameter of a via conductor 33 formed in an insulating layer 31 (a diameter of the via conductor 33 at the upper surface of the conductor layer 32) is about 100 μm.

Similar to the conductor layers 12 and the via conductors 13, the conductor layers (22, 32) and the via conductors (23, 33) may be constituted to each have a multilayer structure, for example, can each have a two-layer structure including a metal film layer and a plating film layer. The second build-up part 20 and the third build-up part 30 do not include fine wiring patterns such as the fine wirings (FW) of the first build-up part 10. In such a case, of the two-layer structure of each of the conductor layers 22 and the via conductors 23, as well as the conductor layers 32 and the via conductors 33, the metal film layer can be an electroless plating film layer (for example, an electroless copper plating film layer) formed by an electroless plating film, and the plating film layer can be an electrolytic plating film layer (for example, an electrolytic copper plating film layer) formed by an electrolytic plating film.

In the example of FIG. 1, the wiring substrate 1 further includes a solder resist layer (SR) formed on the second surface (1B), which is constituted by the surfaces of the insulating layer 31 and the conductor layer 32. The solder resist layer (SR) is formed, for example, using a photosensitive polyimide resin or epoxy resin. Openings (SRa) are formed in the solder resist layer (SR), and conductor pads (32p) included in the conductor layer 32 of the third build-up part 30 are exposed from the openings (SRa).

The second surface (1B) of the wiring substrate 1 on the opposite side with respect to the component mounting surface of the wiring substrate 1 can be a connection surface that is to be connected to an external element such as an external wiring substrate (for example, a motherboard of any electrical device) when the wiring substrate 1 itself is mounted on the external element. The conductor pads (32p) can be connected to any substrate, electronic component, mechanism element, or the like. The wiring substrate 1 has a rectangular shape with each side measuring 80 mm or more and 240 mm or less in a plan view. Here, the term “plan view” means viewing an object along the thickness direction of the wiring substrate 1.

FIG. 2 illustrates a wiring substrate (la) as another example of a wiring substrate manufactured using the manufacturing method of the embodiment. The wiring substrate (la) has a first build-up part 10 having a first surface (10F) and a second surface (10B), and a solder resist layer (SR) that covers the second surface (10B). A conductor layer 12 is exposed from openings (SRa) formed in the solder resist layer (SR). That is, the first surface (1F) of the wiring substrate (la) is constituted by the first surface (10F) of the first build-up part 10, and the second surface (1B) of the wiring substrate (la) is constituted by the second surface (10B) of the first build-up part 10. When a wiring substrate manufactured using the method for manufacturing a wiring substrate of the embodiment does not include any build-up parts other than the first build-up part 10, it can have the form of the wiring substrate (la) as illustrated.

Next, with reference to FIGS. 3A-3P, a method for manufacturing a wiring substrate of the embodiment is described using a case where the wiring substrate 1 illustrated in FIG. 1 is manufactured as an example. In the manufacturing method to be described below, each structural element to be formed can be formed using a material exemplified as a material of the corresponding structural element in the description of the wiring substrate 1 in FIG. 1, unless otherwise specified. In the following description about the method for manufacturing the wiring structure 1, a side closer to a core material (GS1) constituting a first support substrate (SP1), on a surface of which the first build-up part 10 is formed, is referred to as “lower” or a “lower side,” and a side farther from the first support substrate (SP1) is referred to as “upper” or an “upper side.” Therefore, of each element constituting the wiring structure 1, a surface facing the first support substrate (SP1) is referred to as a “lower surface,” and a surface facing the opposite side with respect to the first support substrate (SP1) is also referred to as an “upper surface.”

First, as illustrated in FIG. 3A, the first support substrate (SP1) is prepared. The first support substrate (SP1) has, as two surfaces orthogonal to its thickness direction, a first surface (SP1a) and a second surface (SP1b) on the opposite side with respect to the first surface (SP1a). The first support substrate (SP1) includes the core material (GS1) having a surface (GS1A) on one side and another surface (GS1B) on the opposite side with respect to the surface (GS1A). The first support substrate (SP1) includes, in addition to the core material (GS1), a first metal film layer (ML1) laminated on the surface (GS1A) of the core material (GS1), and a second metal film layer (ML2) laminated on the first metal film layer (ML1) via an adhesive layer (AL1). The core material (GS1) is a glass substrate formed of a glass material, and therefore, the core material (GS1) is also referred to as a glass substrate (GS1). The first and second metal film layers (ML1, ML2) are metal film layers formed by, for example, electroless plating or sputtering. In the illustrated example, the second surface (SP1b) of the first support substrate (SP1) is constituted by the surface (GS1B) of the core material (GS1).

In the following, in FIG. 3A as well as in FIGS. 3B to 3P, an example is illustrated in which one wiring substrate is formed on the first surface (SP1a) of the first support substrate (SP1), and a method for manufacturing the wiring substrate is described. However, multiple wiring substrates can be formed on the first support substrate (SP1). Specifically, the first surface (SP1a) of the first support substrate (SP1) has one or multiple continuous product areas, and a laminate (build-up part) including one wiring substrate in each product area is formed on the first surface (SP1a). When the first surface (SP1a) has multiple product areas, wiring substrates are manufactured by dividing the formed laminate for each product area.

As a material used for the glass substrate (GS1) constituting the first support substrate (SP1), a glass material is adopted with a thermal expansion coefficient that satisfies a predetermined relationship with a thermal expansion coefficient of the insulating layer 11 (see FIGS. 3C to 3J), which is laminated on the first support substrate (SP1). Specifically, as a material used for the glass substrate (GS1), a material is adopted such that a difference in thermal expansion coefficient between a material constituting the glass substrate (GS1) and a material constituting the insulating layer 11 is 13 ppm/° C. or less. The glass material used for the glass substrate (GS1) can have a thermal expansion coefficient of, for example, 8 ppm/° C. or more. Specifically, as a glass material used for the glass substrate (GS1), borosilicate glass, for example, can be used. In the illustration, the first and second metal film layers (ML1, ML2) are each depicted as a single layer, but they may each include multiple layers. For example, the first and second metal film layers (ML1, ML2) can each have a two-layer structure including a titanium layer and a copper layer. The adhesive layer (AL1) can contain, for example, an azobenzene-based polymer adhesive that can be attached or detached by irradiation with light.

Formation of the first build-up part 10, to be described later with reference to FIGS. 3B to 3J, is performed only on the upper side of the surface (GS1A) of the glass substrate (GS1). Therefore, the first surface (SP1a) of the first support substrate (SP1) preferably has good flatness. The first surface (SP1a) of the first support substrate (SP1) has, for example, a flatness of ±2.5 μm or less. Here, “flatness” is an indicator that allows smoothness (uniformity) of a flat surface to be expressed numerically, and is based on or conforms to JIS B 0621-1984. Therefore, a flatness of ±2.5 μm or less indicates that concave or convex deformation of the first support substrate (SP1) in the thickness direction relative to a reference virtual plane is 2.5 μm or less. Further, it is desirable that warping is unlikely to occur in the first support substrate (SP1) during a process of forming the build-up part on the first surface (SP1a). From a point of view of suppressing the warping, the glass substrate (GS1) constituting the first support substrate (SP1) can have a thickness of, for example, 0.7 mm or more.

Next, as illustrated in FIG. 3B, a conductor layer 12 having multiple conductor pads (12p) is formed on the first surface (SP1a) of the first support substrate (SP1). In forming the conductor layer 12 in contact with the first support substrate (SP1), for example, a plating resist is formed on the metal film layer (ML2), and openings corresponding to pattern formation regions of the conductor pads (12p) are formed in the plating resist, for example, using a photolithography technology. Next, a plating film layer 122 is formed in the openings by electrolytic plating using the metal film layer (ML2) as a seed layer. After the formation of the plating film layer 122, the plating resist is removed, and the state illustrated in FIG. 3B is formed.

Next, as illustrated in FIG. 3C, an insulating layer 11 is laminated to cover upper and side surfaces of the conductor layer 12, as well as the first surface (SP1a) of the first support substrate (SP1) exposed from the conductor patterns of the conductor layer 12. The insulating layer 11 is formed by thermocompression bonding a resin molded into a film-like shape. For the formation of the insulating layer 11, a material with a thermal expansion coefficient differing from that of the glass substrate (GS1) by 13 ppm/° C. or less is used. Therefore, a degree of warping that can occur due to a difference in thermal expansion coefficient between the glass substrate (GS1) and the insulating layer 11 during the formation of the insulating layer 11 on the glass substrate (GS1) and subsequent formation of a conductor layer 12 on the insulating layer 11, to be described later with reference to FIGS. 3D to 3H, can be suppressed to a relatively small.

As the insulating layer 11, for example, an insulating resin such as an epoxy resin or a phenol resin can be used. A fluorine resin, a liquid crystal polymer (LCP), a fluoroethylene resin (PTFE), a polyester resin (PE), or a modified polyimide resin (MPI) also may be used. The insulating layer 11 is formed to have a thickness of about 7.5 μm to 10 μm. As described above, the thermal expansion coefficient of the glass substrate (GS1) is, for example, 8 ppm/° C. or more. As the resin material constituting the first insulating layer 11, for example, a resin material having a thermal expansion coefficient of 25 ppm/° C. or less can be preferably adopted.

Subsequently, through holes (11a) are formed in the insulating layer 11 at positions where via conductors 13 (see FIG. 3G) are to be formed by, for example, irradiation with CO₂ laser, excimer laser, or the like. As described above, in the method for manufacturing the wiring substrate of the embodiment, the degree of warping that can occur due to the difference in thermal expansion coefficient between the glass substrate (GS1) and the insulating layer 11 is relatively small, and the surface of the insulating layer 11 has relatively good flatness. Therefore, it is thought that the through holes (11a) can be formed relatively accurately at positions corresponding to the locations where the via conductors 13 are to be formed. The through holes (11a) can be formed such that (a depth of the through holes (11a))/(a diameter of the through holes (11a)) is about 0.5 or more and about 1.0 or less. Here, “the depth of the through holes (11a)” means a shortest distance between the upper surface of the conductor layer 12 and the upper surface of the insulating layer 11, and “the diameter of the through holes (11a)” means a longest distance between two points on an outer periphery of each of the through holes (11a) in a plan view at the upper surface of the insulating layer 11. The through holes (11a) can be formed to each have a diameter of about 10 μm.

Although not illustrated, the formation of the through holes (11a) by irradiation with laser such as CO₂ laser may, in some cases, be performed by irradiating laser while protecting the upper surface of the insulating layer 11 by covering the upper surface with a protective film such as a polyethylene terephthalate (PET) film. Further, after the formation of the through holes (11a), a desmear treatment may, in some cases, be performed to prevent a decrease in adhesion or an increase in a resistance component or the like during the formation of the conductor layer 12 due to a processing-modified substance occurring at bottoms of the through holes (11a). The desmear treatment can preferably be a dry desmear treatment using a plasma gas. The desmear treatment can also be performed while protecting the surface of the insulating layer 11 in a state in which a protective film such as a polyethylene terephthalate (PET) film is formed on the surface of the insulating layer 11.

Next, as illustrated in FIG. 3D, a metal film layer 121 is formed on inner walls of the through holes (11a) and on the surface of the insulating layer 11 by electroless plating, sputtering, or the like. Preferably, the metal film layer 121 can be a sputtering film formed by sputtering. When a protective film is provided on the surface of the insulating layer 11 during the formation of the through holes (11a) and/or during the desmear treatment, the protective film can be peeled off before the formation of the metal film layer 121.

Next, as illustrated in FIG. 3E, for example, a dry film resist containing a photosensitive epoxy resin is adhered onto the metal film layer 121, and a resist layer (RL1) is formed in contact with an upper surface of the metal film layer 121. Subsequently, the resist layer (RL1) is subjected to exposure. In the method for manufacturing the wiring substrate of the embodiment, direct imaging exposure having a relatively high resolution is performed in the process of exposing the resist layer (RL1). In the direct imaging exposure, a photomask is not used, and irradiation light (L) is directly irradiated onto the resist layer (RL1). As a light source for the irradiation light (L), for example, a semiconductor laser with a wavelength of 350 nm to 410 nm or an ultra-high-pressure mercury lamp can be used. The irradiation light (L) is scanned according to drawing patterns corresponding to the conductor patterns of the first conductor layer 12 to be formed on the insulating layer 11 (see FIG. 3H). An exposure amount can be determined by the illuminance of the exposure light source and a scanning speed of the irradiation light (L).

In the method for manufacturing the wiring substrate, each product area on the first surface (SP1a) of the first support substrate (SP1) has a rectangular shape with each side measuring 80 mm or more and 240 mm or less in a plan view. Therefore, the laminate (build-up part) formed across one or multiple product areas of the first surface (SP1a) of the first support substrate (SP1) has at least a rectangular shape with each side measuring 80 mm or more in a plan view. In this way, when a relatively large-sized laminate is manufactured, in the formation of the resist layer (RL1), exposure using a photomask that limits a range that can be exposed in one exposure may require repeated exposures across different ranges, which, in some cases, can lead to an increase in the number of processes in the exposure process. In contrast, in the direct imaging exposure, the entire area of the wiring substrate is scanned with the irradiation light in one exposure, so an increase in the number of processes in the exposure process is suppressed, and therefore the yield in the manufacturing of the wiring substrate may be improved.

Next, as illustrated in FIG. 3F, resist patterns corresponding to the conductor patterns (see FIG. 3H) of the first conductor layer 12 to be formed on the insulating layer 11 are formed in the resist layer (RL1). Specifically, after the above-described process of exposing the resist layer (RL1) is completed, the resist layer (RL1) is developed to form openings (RL10), using a developer including a sodium carbonate aqueous solution which can contain, for example, a surfactant, a defoaming agent, a small amount of an organic solvent for promoting development, and the like. When the wirings (FW) (see FIG. 3H) are included as conductor patterns of the first conductor layer 12 to be formed on the insulating layer 11, the openings (RL10) corresponding to the wirings (FW) can be formed to have a minimum opening width of 2 μm or less and a minimum inter-opening distance of 2 μm or less.

As described above, in the method for manufacturing the wiring substrate of the embodiment, the difference in thermal expansion coefficient between the glass substrate (GS1) and the insulating layer 11 is relatively small, being 13 ppm/° C. or less. Consequently, the degree of warping that can occur in the first support substrate (SP1) and the insulating layer 11 during a manufacturing process of the wiring substrate is relatively small. Therefore, at the point when the exposure to the resist layer (RL1) is performed, as described with reference to FIG. 3E, it is thought that the resist layer (RL1) has relatively good flatness. It is thought that the irradiation light (L) is scanned over the resist layer (RL1) on the insulating layer 11 according to drawing patterns that precisely correspond to the conductor patterns of the first conductor layer 12 (see FIG. 3H) to be formed. Therefore, it is thought that the openings (RL10) formed in the resist layer (RL1) by development precisely correspond to the conductor patterns of the first conductor layer 12 (see FIG. 3H) to be formed.

Next, as illustrated in FIG. 3G, a plating film layer 122 is formed in the openings (RL10) of the resist layer (RL1) by electrolytic plating using the metal film layer 121 as a power feeding layer. The through holes (11a) are completely filled with the plating film layer 122, and the via conductors 13 are formed.

Next, the resist layer (RL1) is removed using an alkaline peeling solution, and then a portion of the metal film layer 121 that is not covered by the plating film layer 122 is removed by etching. As a result, as illustrated in FIG. 3H, a conductor layer 12 having a two-layer structure including the metal film layer 121 and the plating film layer 122 and having the fine wirings (FW) is formed. For example, the conductor layer 212 can be formed to have a thickness of 7 μm or less. The wirings (FW) can be formed to have a minimum wiring width of 2 μm or less, a minimum inter-wiring distance of 2 μm or less, and aspect ratios of, for example, 2.0 or more and 4.0 or less. As described above with reference to FIG. 3F, the formation of the openings (RL10) in the resist layer (RL1) that correspond relatively accurately to the conductor patterns to be formed is thought to allow for the more precise formation of the conductor layer 12 with such relatively fine wirings (FW).

Next, as illustrated in FIG. 3I, using similar methods to the methods for forming the insulating layer 11, the conductor layer 12 and the via conductors 13 described above, on the conductor layer 12 and the insulating layer 11, a desired number of insulating layers 11 and conductor layers 12, and via conductors 13 penetrating the respective insulating layers, are formed. In the method for manufacturing the wiring substrate of the embodiment, at least three insulating layers 11 and at least three conductor layers 12 are formed on the first support substrate (SP1). As the number of the insulating layers 11 and conductor layers 12 laminated on the first support substrate (SP1) increases, the degree of warping due to the difference in thermal expansion coefficient between the insulating layers 11 and the glass substrate (GS1) can become greater. However, in the method for manufacturing the wiring substrate of the embodiment, the difference in thermal expansion coefficient between the insulating layers 11 and the glass substrate (GS1) is relatively small, being 13 ppm/° C. or less. Therefore, even when the number of the insulating layers 11 increases, the resulting warping is suppressed to a relatively small degree. In the case where multiple insulating layers 11 and multiple conductor layers 12 are formed on the first support substrate (SP1), the accurate formation of the through holes (11a) and the accurate formation of the conductor layers 12, as described above, can be realized.

Next, as illustrated in FIG. 3J, on the upper side of the conductor layer 12, the uppermost insulating layer 11 and conductor layer 12 among the insulating layers 11 and conductor layers 12 of the first build-up part 10 are formed. The formation of the first build-up part 10 on the first surface (SP1a) of the first support substrate (SP1) is completed. As illustrated, the uppermost conductor layer 12 that does not include the wirings (FW) may be formed using a method similar to that for the formation of the insulating layer 11 and the conductor layer 12 on the insulating layer 11 described above (the method that includes direct imaging exposure for a resist layer). However, it may also be formed using a method including formation of resist patterns by exposure using a photomask for a resist layer. At the point when the first build-up part 10 has been formed, the flatness of the surface of the laminate (build-up part) formed on the first surface (SP1a) of the first support substrate (SP1) that faces the glass substrate (that is, the surface in contact with the first surface (SP1a) of the first support substrate (SP1)) is, for example, ±2.5 μm or less.

In the method for manufacturing the wiring substrate of the embodiment, in the formation of the multiple conductor layers 12 that constitute the first build-up part 10, it is sufficient when any one of the conductor layers 12 formed on the insulating layers 11 is formed using a method that includes direct imaging exposure for the resist layer. Therefore, for example, in the illustrated example, the lowermost conductor layer 12 in the first build-up part 10 (the conductor layer 12 in contact with the first support substrate (SP1)), which does not include the wirings (FW), also may be formed using a method that includes formation of resist patterns by exposure using a photomask for a resist layer, or may be formed using a method that includes the direct imaging exposure.

Subsequently, as illustrated in FIG. 3K, the lowermost insulating layer 21 of the second build-up part 20 (see FIG. 3N) is laminated on the uppermost insulating layer 11 and conductor layer 12 of the first build-up part 10. The thickness of the insulating layer 21 can be different from that of each of the insulating layers 11 constituting the first build-up part 10. The insulating layer 21 can be formed to have a thickness of, for example, about 20 μm to 30 μm. The insulating layer 21 can be constituted by an insulating resin similar to the insulating resin constituting the insulating layers 11. A film (21F) formed of a resin such as polyethylene terephthalate, which is peelably bonded to the insulating layer 21, is laminated on the insulating layer 21.

Next, as illustrated in FIG. 3L, two first build-up parts 10, each with an insulating layer 21 and a film (21F) attached, are respectively adhered to two main surfaces (surfaces orthogonal to a thickness direction) of a second support substrate (SP2) via first support substrates (SP1). Each main surface of the second support substrate (SP2) and the second surface (SP1b) of each first support substrate (SP1) are bonded via an adhesive layer (AL2) constituted by any adhesive. The second support substrate (SP2) can be, for example, a glass substrate similar to the core material (GS1) of the first support substrate (SP1). Alternately, for the second support substrate (SP2), a copper clad laminate (CCL), which includes an insulating layer and copper foil thermocompression bonded to both sides of the insulating layer, can be used.

Next, the film (21F) is peeled off from the insulating layer 21. Subsequently, for example, formation of through holes (21a) in the insulating layer 21 by laser irradiation, as well as formation of via conductors 23 having a two-layer structure including a metal film layer 221 and a plating film layer 222, and of a conductor layer 22 on the insulating layer 21, using a so-called semi-additive method, are performed. That is, a metal film layer 221 is formed, for example, by electroless plating, in the through holes (21a) and on the surface of the insulating layer 21, and a plating resist (not illustrated) having openings corresponding to the conductor patterns that the conductor layer 22 is to have is provided on the metal film layer 221. Then, a plating film layer 222 is formed in the openings of the plating resist by electrolytic plating using the metal film layer 221 as a power feeding layer, and the via conductors 23 are formed in the through holes (21a). After that, the plating resist is removed, and further, portions of the metal film layer 221 that are not covered by the plating film layer 222 are removed by etching. The conductor layer 22 can be formed to have a thickness of, for example, 10 μm or more. The conductor layer 22 can be formed to include wirings having, for example, a minimum wiring width of about 4 μm and a minimum inter-wiring distance of about 6 μm. In the formation of the conductor layer 22, for the formation of the openings in the plating resist, exposure by direct imaging described above may be used, or exposure using a photomask also may be used.

In FIG. 3M, as well as FIGS. 3N-3P to be referenced below, the laminate formed on the surface on one side of the second support substrate (SP2) is illustrated, and illustration of a laminate that can be formed on the surface on the opposite side is omitted. However, on the surface on the opposite side of the second support substrate (SP2), a laminate of the form and number illustrated is also formed at the same time.

Next, as illustrated in FIG. 3N, the process of forming the insulating layer 21, the conductor layer 22, and the via conductors 23 described above is repeated to form a desired number of insulating layers 21 and conductor layers 22, as well as via conductors 23 that penetrate the respective insulating layers 21. The formation of the second build-up part 20 on the first build-up part 10 is completed. In FIG. 3N, as well as the following FIGS. 3O and 3P, the metal film layer and plating film layer are not depicted, and the conductor layers (12, 22) are depicted as each having a single-layer structure, similar to that in FIG. 1.

When the wiring substrate 1 illustrated in FIG. 1 is manufactured, the second build-up part 20 is formed on the first support substrate (SP1) via the first build-up part 10, following the lamination of the first build-up part 10 on the first support substrate (SP1). It is thought that, since the second build-up part 20 is formed directly on the first build-up part 10, where the degree of warping that can occur is suppressed to a relatively small level, the second build-up part 20 can also be formed to have good flatness.

Next, as illustrated in FIG. 3O, on the uppermost insulating layer 21 and conductor layer 22 of the second build-up part 20, the insulating layers 31, the conductor layers 32, and the via conductors 33 penetrating the insulating layers 31, of the third build-up part 30 are formed using methods similar to those used for forming the insulating layers 21, the conductor layers 22, and the via conductors 23. As an insulating resin forming the insulating layers 31, a prepreg containing an insulating resin such as epoxy resin or BT resin impregnated in a reinforcing material (core material) constituted by glass fiber can be used. As illustrated, the third build-up part 30 including two insulating layers 31 and two conductor layers 32 is formed. Subsequently, the solder resist layer (SR) is formed by forming a photosensitive epoxy resin or polyimide resin layer on the surfaces of the uppermost insulating layer 31 and the conductor layer 32. Then, the openings (SRa) exposing the conductor pads (32p) are formed using a photolithography technology.

Next, as illustrated in FIG. 3P, the first support substrate (SP1) and the second support substrate (SP2) are removed from the laminate including the first build-up part 10. In the removal of the first support substrate (SP1) from the first build-up part 10, for example, after the adhesive layer (AL1) is irradiated with laser and softened, the second metal film layer (ML2) of the first support substrate (SP1) is peeled off from the adhesive layer (AL1). The lower surface of the second metal film layer (ML2) below the conductor pads (12p) is exposed. Although not illustrated in FIG. 3P, the removal of the first support substrate (SP1) is also similarly performed on the side of the second support substrate (SP2) opposite to the side illustrated. Subsequently, the second metal film layer (ML2) is removed by etching. The lower surfaces of the conductor pads (12p) and the lower surface of the insulating layer 11 are exposed. A laminate that can include multiple wiring substrates is divided by product areas, forming individual independent wiring substrates. The wiring substrate 1 illustrated in FIG. 1 is completed.

The method for manufacturing the wiring substrate of the embodiment is not limited to the method described with reference to FIGS. 3A-3P, and the conditions, processing order and the like of the method can be modified as appropriate. Further, it is also possible that a specific process is omitted or another process is added. The method for manufacturing a wiring substrate of the embodiment may include at least alternately laminating three or more conductor layers and three or more insulating layers on only one surface of a glass substrate. The difference in thermal expansion coefficient between the glass substrate and the insulating layers is 13 ppm/° C. or less, and the lamination of the conductor layers includes formation of resist patterns by direct imaging exposure. For example, a solder resist layer having openings exposing the conductor pads (12p) may be formed on the conductor pads (12p) and insulating layer 11, which are exposed after the removal of the second metal film layer (ML2) by etching. Further, conductor bumps connecting to the conductor pads (12p) may be formed in the openings provided in the solder resist layer. A plating layer including a nickel layer and a tin layer may be formed on the surfaces of the conductor bumps. It is also possible that the second and third build-up parts are not formed, or in addition to the second and third build-up parts, a fourth build-up part is formed.

Japanese Patent Application Laid-Open Publication No. 2020-4926 describes a method for manufacturing a wiring substrate that includes a second wiring substrate and a first wiring substrate. The first wiring substrate is formed by laminating an insulating resin and a wiring layer onto a support substrate that includes a glass substrate. The wiring layer on the insulating resin is formed by filling resist pattern openings with conductors. After the first wiring substrate is bonded to the second wiring substrate, the support substrate is peeled off.

In the method for manufacturing a wiring substrate described in Japanese Patent Application Laid-Open Publication No. 2020-4926, it is thought that warping may occur in the support substrate, insulating resin, and wiring layer during the lamination of the insulating resin and wiring layer onto the support substrate. It is thought that a defect may occur during the formation of patterns of the wiring layer. It is thought that this may lead to a lower yield in the manufacturing of the wiring substrate.

A method for manufacturing a wiring substrate according to an embodiment of the present invention includes preparing a glass substrate having one surface provided with one or multiple product areas and another surface on the opposite side with respect to the one surface, and forming a build-up part by laminating conductor layers and insulating layers only on the one surface across the one or multiple product areas. The laminating of the conductor layers and insulating layers includes alternately laminating three or more conductor layers and three or more insulating layers. A difference in thermal expansion coefficient between the glass substrate and the insulating layers is 13 ppm/° C. or less. The product areas each have a rectangular shape with each side measuring 80 mm or more and 240 mm or less in a plan view. The laminating of the conductor layers includes forming a resist layer having resist patterns and forming conductor patterns according to the resist patterns. The laminating of the conductor layers includes forming wirings included in the conductor patterns such that the wirings have a minimum width of 2 μm or less and a minimum inter-wiring distance of 2 μm or less. The forming of the resist layer having the resist patterns includes exposing the resist layer by direct imaging exposure.

According to an embodiment of the present invention, the degree of warping that may occur during the process of forming the build-up part is suppressed, and the wiring substrate can be manufactured with high yield and efficiency.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
preparing a glass substrate having at least one product area formed on a surface thereof; and
forming a build-up part comprising a plurality of conductor layers and a plurality of insulating layers on the surface of the glass substrate across the at least one product area,
wherein the glass substrate is formed such that the at least one product area has a rectangular shape with each side in a range of 80 mm to 240 mm, the forming the build-up part includes alternately laminating three or more conductor layers and three or more insulating layers such that a difference in thermal expansion coefficient between the glass substrate and the insulating layers is 13 ppm/° C. or less, the laminating the conductor layers includes forming a resist layer having a resist pattern and forming a conductor pattern including a plurality of wirings according to the resist pattern such that the plurality of wirings has a minimum width of 2 μm or less and a minimum inter-wiring distance of 2 μm or less, and the forming the resist layer includes exposing the resist layer by direct imaging exposure.

2. The method for manufacturing a wiring substrate according to claim 1, wherein the glass substrate has a thermal expansion coefficient of 8 ppm/° C. or more.

3. The method for manufacturing a wiring substrate according to claim 1, wherein the glass substrate has a thickness of 0.7 mm or more.

4. The method for manufacturing a wiring substrate according to claim 1, wherein the glass substrate includes borosilicate glass.

5. The method for manufacturing a wiring substrate according to claim 1, wherein each of the insulating layers has a thermal expansion coefficient of 25 ppm/° C. or less.

6. The method for manufacturing a wiring substrate according to claim 1, wherein the build-up part is formed such that a surface of the build-up part facing the glass substrate has a flatness of ±2.5 μm or less.

7. The method for manufacturing a wiring substrate according to claim 1, wherein the conductor pattern is formed such that each of the wirings in the conductor pattern has an aspect ratio in a range of 2.0 to 4.0.

8. The method for manufacturing a wiring substrate according to claim 1, further comprising:
forming a second build-up part on the build-up part on an opposite side with respect to the glass substrate such that the second build-up part includes an insulating layer having a thickness that is different from a thickness of each of the insulating layers in the build-up part.

9. The method for manufacturing a wiring substrate according to claim 2, wherein the glass substrate has a thickness of 0.7 mm or more.

10. The method for manufacturing a wiring substrate according to claim 2, wherein the glass substrate includes borosilicate glass.

11. The method for manufacturing a wiring substrate according to claim 2, wherein each of the insulating layers has a thermal expansion coefficient of 25 ppm/° C. or less.

12. The method for manufacturing a wiring substrate according to claim 2, wherein the build-up part is formed such that a surface of the build-up part facing the glass substrate has a flatness of ±2.5 μm or less.

13. The method for manufacturing a wiring substrate according to claim 2, wherein the conductor pattern is formed such that each of the wirings in the conductor pattern has an aspect ratio in a range of 2.0 to 4.0.

14. The method for manufacturing a wiring substrate according to claim 2, further comprising:
forming a second build-up part on the build-up part on an opposite side with respect to the glass substrate such that the second build-up part includes an insulating layer having a thickness that is different from a thickness of each of the insulating layers in the build-up part.

15. The method for manufacturing a wiring substrate according to claim 3, wherein the glass substrate includes borosilicate glass.

16. The method for manufacturing a wiring substrate according to claim 3, wherein each of the insulating layers has a thermal expansion coefficient of 25 ppm/° C. or less.

17. The method for manufacturing a wiring substrate according to claim 3, wherein the build-up part is formed such that a surface of the build-up part facing the glass substrate has a flatness of ±2.5 μm or less.

18. The method for manufacturing a wiring substrate according to claim 3, wherein the conductor pattern is formed such that each of the wirings in the conductor pattern has an aspect ratio in a range of 2.0 to 4.0.

19. The method for manufacturing a wiring substrate according to claim 3, further comprising:
forming a second build-up part on the build-up part on an opposite side with respect to the glass substrate such that the second build-up part includes an insulating layer having a thickness that is different from a thickness of each of the insulating layers in the build-up part.

20. The method for manufacturing a wiring substrate according to claim 4, wherein each of the insulating layers has a thermal expansion coefficient of 25 ppm/° C. or less.
